(19) United States
(12) Patent Application Publication
(10) Pub. No.: US 2009/0044900 A1
(43) Pub. Date: Feb. 19, 2009

(54) Method of and apparatus for laminated substrate assembly

(75) Inventors: Kazuyoshi Suehara, Shizuoka-ken (JP); Yasuhisa Watanabe, Shizuoka-ken (JP); Haruhito Arimitsu, Shizuoka-ken (JP); Hidenori Gotoh, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: Fujifilm Corporation, Minato-ku (JP)

(21) Appl. No.: 11/887,006

(22) PCT Filed: Mar. 16, 2006
(86) PCT No.: PCT/JP2006/305749

§ 371 Date: Sep. 24, 2007

(30) Foreign Application Priority Data
Mar. 23, 2005 (JP) 2005-083339

(51) Int. Cl. B32B 38/10; B32B 37/04; B44C 1/17; G03F 7/16

(52) U.S. Cl. 156/239; 156/230; 156/498

(57) ABSTRACT

A manufacturing apparatus has a joining mechanism for bonding a photosensitive web to a glass substrate such that a cushion layer thereof faces the glass substrate, thereby to produce a joined substrate. The manufacturing apparatus also has a cooling mechanism for forcibly cooling the joined substrate with cooling air, a heating mechanism for heating the cushion layer to a temperature in a predetermined temperature range up to a glass transition temperature thereof, and a peeling mechanism for peeling off a base film of the photosensitive web from the heated joined substrate. The cooling mechanism, the heating mechanism, and the peeling mechanism are successively arranged in the direction in which the joined substrate is fed along.

### TECHNICAL FIELD

The present invention relates to a method of and an apparatus for manufacturing a laminated substrate assembly by bonding a laminated body including a support layer and at least one resin layer laminated thereon, to a substrate such that the resin layer faces the substrate, and thereafter peeling off the support layer from the resin layer.

### BACKGROUND ART

Substrates for liquid crystal panels, substrates for printed wiring boards, and substrates for PDP panels, for example, have a photosensitive sheet (photosensitive web) having a photosensitive material (photosensitive resin) layer and applied to substrate surfaces. The photosensitive sheet comprises a photosensitive material layer and a protective film that are successively deposited on a flexible plastic support.

An applying apparatus for applying such a photosensitive sheet usually operates to feed substrates such as glass substrates, resin substrates, or the like at spaced intervals, peel off the protective film from the photosensitive sheet, and thereafter apply the photosensitive material layer to the substrates.

For example, Japanese Laid-Open Patent Publication No. 8-183146 discloses a method of laminating a dry resist film. According to the disclosed laminating method, as shown in FIG. 17 of the accompanying drawings, a substrate preheater, a laminator, a substrate cooler, an on-substrate film cutter, and a film remover are successively arranged along the direction in which successive substrates 1 are fed along. Each of the substrates 1 is heated to a predetermined temperature by a preheater 2 of the substrate preheater, and then sent to the laminator.

A dry resist film 4 comprises a base film, a resist layer disposed on the base film, and a cover film 5 disposed on the resist layer. The laminator has a pair of laminating rollers 3a, 3b. The substrate 1 and the dry resist film 4 are delivered between the laminating rollers 3a, 3b, which thermally compress the dry resist film 4 against the substrate 1. Before the dry resist film 4 is sent to the laminator, the cover film 5 has been peeled off from the dry resist film 4, exposing the resist layer on the base film. In the laminator, the exposed resist layer of the dry resist film 4 is thermally compressed against the substrate 1 by the laminating rollers 3a, 3b.

The substrate 1 with the dry resist film 4 being thermally bonded thereto is fed by feed rollers 6, and then supplied to the substrate cooler in which the substrate 1 is cooled by a substrate cooling unit 7. When the dry resist film 4 is cooled in the substrate cooler, the resist layer of the dry resist film 4 is hardened and its adhesion to the substrate 1 is increased. When the dry resist film 4 is subsequently cut off by the on-substrate film cutter, the resist layer is prevented from being peeled off due to stresses developed when it is cut off.

Then, a portion of the dry resist film 4 that interconnects successive substrates 1 is severed by cutting blades of an on-substrate film cutting unit 8 of the on-substrate film cutter, leaving a cut strip of the dry resist film 4 on and between confronting ends of the interconnected substrates 1. The substrates 1 are then sent to the film remover. In the film remover, the substrates 1 are reheated by heating rollers 9, and the cut strip of the dry resist film 4 which is disposed on and between the confronting ends of the interconnected substrates 1 is removed from the substrates 1 by a film peeling unit 10.

According to the conventional laminating method, the substrates 1 are heated to a temperature in the range from 60° C. to 90° C. by the heating rollers 9 to allow the cut strip of the dry resist film 4 which projects from the ends of the substrates 1, to be easily removed from the substrate 1. However, the temperature of the cut strip of the dry resist film 4 cannot accurately be controlled by the heat from the substrates 1 that are heated by the heating rollers 9. Consequently, if the base film is to be removed from the substrates 1, leaving desired resist layers thereon, the base film alone cannot reliably be peeled off from the substrates. The surface to be peeled off of the base film is not made smooth, and tends to fail to be peeled off. Unwanted resist layers are liable to remain attached to the substrates 1, resulting in a reduction in the quality of the substrates 1.

### DISCLOSURE OF INVENTION

It is a major object of the present invention to provide a method of and an apparatus for manufacturing a high quality laminated substrate assembly efficiently by peeling off a support layer from a resin layer with a simple process and arrangement.

According to the present invention, there are provided a method of and an apparatus for manufacturing a laminated substrate assembly by bonding a laminated body including a support layer and at least one resin layer laminated thereon, to a substrate such that the resin layer faces the substrate, and thereafter, peeling off the support layer from the resin layer to produce a laminated substrate assembly.

A joined substrate, which includes the resin layer and the substrate bonded thereto, is cooled. Thereafter, the resin layer is heated to a temperature in a predetermined temperature range up to a glass transition temperature thereof. Then, the support layer is peeled off from the resin layer, producing the laminated substrate assembly.

Preferably, the support layer should be peeled off from the resin layer while the resin layer is being heated. Further preferably, after the joined substrate which has been heated is cooled, the support layer should be peeled off from the resin layer. This is because cooling the joined substrate reduces the adhesion between the support layer and the resin layer, allowing the support layer to be easily and reliably peeled off from the resin layer.

The resin layer should preferably be heated from the side of the support layer. Since the peel-off interface between the support layer and the resin layer is heated more quickly and accurately to a desired temperature than if it is heated from the side of the substrate, the support layer and the resin layer can be peeled off from each other highly accurately.

Preferably, after the laminated body, which is elongate, has been bonded integrally to a plurality of the substrates, the support layer should be peeled off continuously from each of the substrates to produce the laminated substrate assembly. Further preferably, after the laminated body, which is elongate, has been bonded integrally to a plurality of the substrates, and the laminated body has been cut off between the substrates, the support layer should be peeled off from each of the substrates to produce the laminated substrate assembly.

The laminated body should preferably comprise an elongate photosensitive web in the form of a laminated assembly of the support layer, a thermoplastic resin layer disposed as the resin layer on the support layer, and a photosensitive resin layer disposed on the thermoplastic resin layer and bonded to the substrate. The support layer should preferably be peeled off from the thermoplastic resin layer or the photosensitive resin layer. The predetermined temperature range should preferably comprise a range from 32° C. to 38° C.

According to the present invention, since the resin layer is heated to a temperature in the predetermined temperature range up to the glass transition temperature thereof, residual stresses developed in the resin layer are reliably reduced. Residual stresses tend to be developed in the resin layer when the laminated body is bonded to (thermally compressed against) the substrate while being kept under tension, or when the joined substrate is forcibly cooled after the laminated body has been bonded to the substrate. When the cooled resin layer is heated to a temperature in the predetermined temperature range, the residual stresses developed in the resin layer are effectively reduced to allow the support layer to be peeled off easily well from the resin layer. Consequently, when the support layer is peeled off, it suffers no peeling failures. Therefore, it is possible to efficiently manufacture a laminated substrate assembly of high quality.

The above and other objects, features, and advantages of the present invention will become more apparent from the following description when taken in conjunction with the accompanying drawings in which preferred embodiments of the present invention are shown by way of illustrative example.

### BRIEF DESCRIPTION OF DRAWINGS

FIG. 1 is a schematic side elevational view of a manufacturing apparatus according to a first embodiment of the present invention;

FIG. 2 is an enlarged fragmentary cross-sectional view of an elongate photosensitive web used in the manufacturing apparatus shown in FIG. 1;

FIG. 3 is an enlarged fragmentary cross-sectional view showing the elongate photosensitive web with a masking tape bonded thereto;

FIG. 4 is a diagram showing the relationship between temperatures and tan δ values;

FIG. 5 is a perspective view of a peeling mechanism of the manufacturing apparatus;

FIG. 6 is a perspective view of a portion of the peeling mechanism;

FIG. 7 is a schematic side elevational view of the manufacturing apparatus, showing the manner in which a glass substrate enters between rubber rollers;

FIG. 8 is a schematic view of a portion of the manufacturing apparatus, showing its operation upon completion of a lamination process on a first glass substrate;

FIG. 9 is a fragmentary cross-sectional view of glass substrates to which a photosensitive resin layer is transferred;

FIG. 10 is a schematic view of a portion of the manufacturing apparatus, showing the manner in which the substrate feed rollers are spaced from an end of a joined substrate;

FIG. 11 is a schematic view of a portion of the manufacturing apparatus, showing the manner in which elongate photosensitive webs are severed between joined substrates;

FIG. 12 is a side elevational view showing the manner in which the peeling mechanism operates;

FIG. 13 is a table showing the relationship between surface temperatures of a base film and film peeling failures;

FIG. 14 is a schematic side elevational view of a manufacturing apparatus according to a second embodiment of the present invention;

FIG. 15 is a schematic side elevational view of a heating mechanism of a manufacturing apparatus according to a third embodiment of the present invention;

FIG. 16 is a schematic side elevational view of a heating mechanism of a manufacturing apparatus according to a fourth embodiment of the present invention; and

FIG. 17 is a schematic side elevational view illustrating a conventional method of laminating a dry resist film.

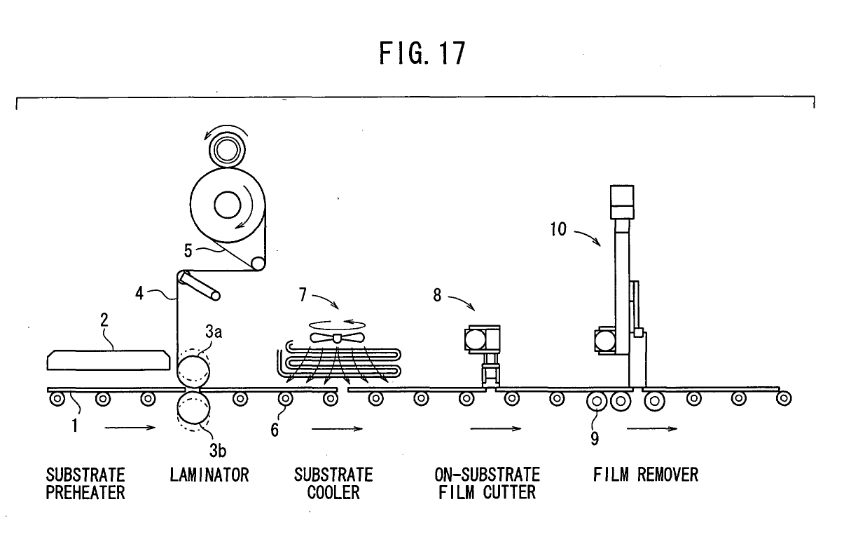

### BEST MODE FOR CARRYING OUT THE INVENTION

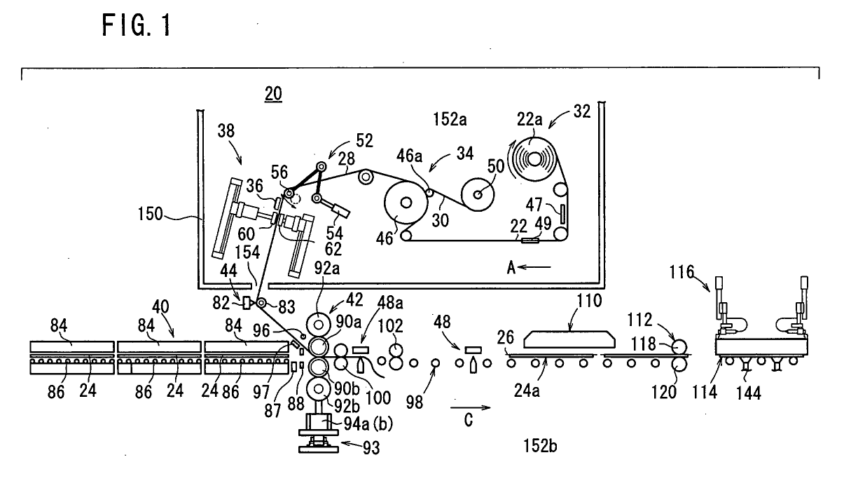

FIG. 1 shows in schematic side elevation an apparatus 20 for manufacturing a photosensitive laminated body (laminated substrate assembly) according to a first embodiment of the present invention. The manufacturing apparatus 20 operates to thermally transfer a photosensitive resin layer 29 (described later) of an elongate photosensitive web 22 to glass substrates 24 in a process of manufacturing printed wiring boards, liquid crystal panels, PDPs, or color filters for use with organic EL panels.

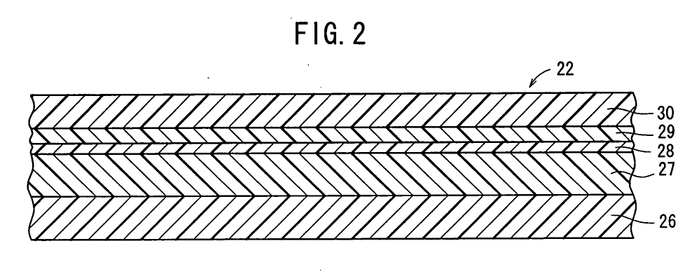

FIG. 2 shows in cross section the photosensitive web (laminated body) 22 that is employed in the manufacturing apparatus 20. The photosensitive web 22 comprises a laminated assembly of a flexible base film (support layer) 26, a cushion layer (thermoplastic resin layer) 27 disposed on the base film 26, an intermediate layer (oxygen blocking film) 28 disposed on the cushion layer 27, a photosensitive resin layer 29 disposed on the intermediate layer 28, and a protective film 30 disposed on the photosensitive resin layer 29.

The base film 26 is made of polyethylene terephthalate (PET). The cushion layer 27 is made of ethylene and vinyl oxide copolymer. The intermediate layer 28 is made of polyvinyl alcohol. The photosensitive resin layer 29 is made of a colored photosensitive resin composition containing an alkali-soluble binder, a monomer, and a photopolymerization initiator and a colorant. The protective film 30 is made of polypropylene.

As shown in FIG. 1, the manufacturing apparatus 20 has a web reel-out mechanism 32 for accommodating a photosensitive web roll 22a in the form of the rolled photosensitive web 22 and reeling out the photosensitive web 22 from the photosensitive web roll 22a, a peeling mechanism 34 for continuously peeling the protective film 30 from the photosensitive web 22, a masking tape applying mechanism 38 for applying masking tapes 36 to the photosensitive resin layer 29 exposed on the surface of the photosensitive web 22, at spaced intervals in a reel-out direction indicated by the arrow A, a substrate feed mechanism 40 for feeding a glass substrate 24 which is heated to a predetermined temperature to a joining position, and a joining mechanism 42 for applying the photosensitive resin layer 29 which has been exposed by peeling off the protective film 30 to the glass substrate 24.

A detecting mechanism 44 for directly detecting masking tapes 36 at the boundary positions of the photosensitive web 22 is disposed upstream of and closely to the joining position in the joining mechanism 42. An inter-substrate web cutting mechanism 48 for cutting the photosensitive web 22 between adjacent glass substrates 24 is disposed downstream of the joining mechanism 42. A web leading end cutting mechanism 48a that is used when the manufacturing apparatus 20 starts to operate, suffers a trouble, or ejects a defective film is disposed upstream of the inter-substrate web cutting mechanism 48.

A joining base 47 for joining the trailing end of a photosensitive web 22 that has essentially been used up and the leading end of a photosensitive web 22 that is to be newly used is disposed downstream of and closely to the web reel-out mechanism 32. The joining base 47 is followed downstream by a film end position detector 49 for controlling a transverse shift of the photosensitive web 22 due to a winding irregularity of the photosensitive web roll 22a. The film end of the photosensitive web 22 is positionally adjusted by transversely moving the web reel-out mechanism 32. However, the film end of the photosensitive web 22 may be adjusted by a position adjusting mechanism combined with rollers. The web reel-out mechanism 32 may comprise a multi-shaft mechanism including two or three unreeling shafts for supporting the photosensitive web roll 22a and feeding out the photosensitive web 22.

The peeling mechanism 34 has a suction drum 46 for reducing variations of the tension to which the supplied photosensitive web 22 is subjected for thereby stabilizing the tension of the photosensitive web 22 when it is subsequently laminated. The peeling mechanism 34 also has a peeling roller 46a disposed closely to the suction drum 46. The protective film 30 that is peeled off from the photosensitive web 22 at a sharp peel-off angle is continuously wound by a protective film takeup unit 50.

A tension control mechanism 52 for imparting tension to the photosensitive web 22 is disposed downstream of the peeling mechanism 34. The tension control mechanism 52 has a cylinder 54 that is actuatable to angularly displace or swing a tension dancer 56 to adjust the tension of the photosensitive web 22 that the tension dancer 56 is held in rolling contact with. The tension control mechanism 52 may be employed only when necessary, and may be dispensed with.

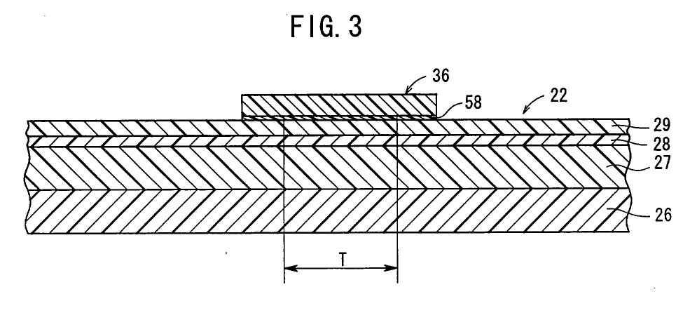

As shown in FIG. 3, the masking tape applying mechanism 38 applies each masking tape 36 to the photosensitive resin layer 29, from which the protective film 30 has been peeled off, across a substrate interval T. For example, the masking tape 36 comprises a base of polyethylene terephthalate (PET) and an adhesive layer 58 of acrylic adhesive, silicone adhesive, a combination of acrylic adhesive and silicone adhesive, rubber adhesive or the like which is disposed on one surface of the base which is to be bonded to the photosensitive resin layer 29. The other surface of the masking tape 36 is free of an adhesive layer, and should preferably be treated with a non-sticky film, e.g., coated with a fluorine resin film or the like.

As shown in FIG. 1, the masking tape applying mechanism 38 has an attracting member 60 for attracting a masking tape 36 and an applying back base 62 for backing the photosensitive resin layer 29. The attracting member 60 and the applying back base 62 operate in coaction to apply the masking tape 36 to the photosensitive resin layer 29 at a predetermined position thereon.

The detecting mechanism 44 comprises a photoelectric sensor 82 such as a laser beam sensor, a photosensor, or the like. The photoelectric sensor 82 directly detects a change in the intensity of light passing through the photosensitive web 22 when a masking tape 36 blocks the passing light. The photoelectric sensor 82 produces a boundary position signal when it detects such a change in the intensity of the passing light. The photoelectric sensor 82 is positioned in confronting relation to a backup roller 83 with the photosensitive web 22 traveling therebetween in rolling contact with the backup roller 83.

The detecting mechanism 44 may comprise a contactless displacement meter for detecting a masking tape thickness on the photosensitive web 22, or an image inspecting means such as a CCD camera or the like, etc. rather than the photoelectric sensor 82.

The substrate feed mechanism 40 has a plurality of substrate heating units (e.g., heaters) 84 disposed for sandwiching and heating glass substrates 24, and a feeder 86 for feeding glass substrates 24 in the direction indicated by the arrow C. The temperatures of the glass substrates 24 in the substrate heating units 84 are monitored at all times. When the monitored temperature of a glass substrate 24 becomes abnormal, the feeder 86 is inactivated and a warning is issued, and abnormality information is sent to reject and discharge the abnormal glass substrate 24 in a subsequent process, and is also used for quality control and production management. The feeder 86 has an air-floated plate (not shown) for floating and feeding glass substrates 24 in the direction indicated by the arrow C. Instead, the feeder 86 may comprise a roller conveyor for feeding glass substrates 24.

The temperatures of the glass substrates 24 should preferably be measured in the substrate heating units 84 or immediately prior to the joining position according to a contact process (using a thermocouple, for example) or a non-contact process.

Downstream of the substrate heating units 84, there are disposed a stopper 87 for abutting against the leading end of a glass substrate 24 and holding the glass substrate 24, and a position sensor 88 for detecting the position of the leading end of the glass substrate 24. The position sensor 88 detects the position of the leading end of the glass substrate 24 on its way toward the joining position. After the position sensor 88 has detected the position of the leading end of the glass substrate 24, the glass substrate 24 is fed a predetermined distance and is disposed at a predetermined position between rubber rollers 90a, 90b of the joining mechanism 42. Preferably, a plurality of position sensors 88 are disposed at spaced intervals along the feed path for monitoring the times at which a glass substrate 24 reaches the respective positions of the position sensors 88, thereby to check a delay due to a slippage or the like of the glass substrate 24 when the glass substrate 24 starts to be fed. In FIG. 1, glass substrates 24 are heated by the substrate heating units while the glass substrates 24 are being fed. Alternatively, glass substrates 24 may be heated in a batch-heating oven and fed by a robot.

The joining mechanism 42 has a pair of vertically spaced laminating rubber rollers 90a, 90b that can be heated to a predetermined temperature. The joining mechanism 42 also has a pair of backup rollers 92a, 92b held in rolling contact with the rubber rollers 90a, 90b, respectively. The backup roller 92b is pressed against the rubber roller 90b by pressing cylinders 94a, 94b of a roller clamp unit 93.

A contact prevention roller 96 is movably disposed near the rubber roller 90a for preventing the photosensitive web 22 from contacting the rubber roller 90a. A preheating unit 97 for preheating the photosensitive web 22 to a predetermined temperature is disposed upstream of and closely to the joining mechanism 42. The preheating unit 97 comprises a heating means such as an infrared bar heater or the like.

Glass substrates 24 are fed from the joining mechanism 42 through the inter-substrate web cutting mechanism 48 along a feed path 98 which extends in the direction indicated by the arrow C. The feed path 98 comprises an array of rollers including film feed rollers 100 and substrate feed rollers 102 with the web leading end cutting mechanism 48a interposed therebetween. The distance between the rubber rollers 90a, 90b and the substrate feed rollers 102 is equal to or less than the length of one glass substrate 24.

In the manufacturing apparatus 20, the web reel-out mechanism 32, the peeling mechanism 34, the tension control mechanism 52, the masking tape applying mechanism 38, and the detecting mechanisms 44 are disposed above the joining mechanism 42. Conversely, the web reel-out mechanism 32, the peeling mechanism 34, the tension control mechanism 52, the masking tape applying mechanism 38, and the detecting mechanisms 44 may be disposed below the joining mechanism 42, so that the photosensitive web 22 may be vertically inverted, and the photosensitive resin layer 29 may be joined to the lower surfaces of glass substrates 24. Alternatively, all the mechanisms of the manufacturing apparatus 20 may be linearly arrayed.

The manufacturing apparatus 20 has a cooling mechanism 110 disposed downstream of the inter-substrate web cutting mechanism 48 for cooling a joined substrate 24a that is made up of the photosensitive web 22, from which the protective film 30 has been peeled off, and the glass substrate 24 joined to the photosensitive web 22; a heating mechanism 112 for heating the resin layer, e.g., the cushion layer 27, of the cooled joined substrate 24a to a temperature in a predetermined temperature range (described later) up to, e.g., equal to or below, the glass transition temperature (Tg); and a peeling mechanism 116 for peeling off the base film 26 from the joined substrate 24a to produce a photosensitive laminated body 114.

The cooling mechanism 110 supplies cold air to a joined substrate 24a to cool the joined substrate 24a. Specifically, the cooling mechanism 110 supplies cold air having a temperature of 10° C. at a rate ranging from 0.5 to 2.0 m/min. The heating mechanism 112 comprises a heating roller 118 disposed on the side of the base film 26 of the joined substrate 24a and a backup roller 120 disposed on the side of the glass substrate 24 in vertical alignment with the heating roller 118.

The heating roller 118 is internally or externally heated by an electromagnetic induction heater, for example, and is held in direct contact with the base film 26 to heat the cushion layer 27 through the base film 26. The heating roller 118 may alternatively be heated by a sheathed heater, a hot-water (liquid) heater, or the like, rather than the electromagnetic induction heater. The heating roller 118 may comprise a rubber roller, a metal roller, a cloth-wound roller, a resin roller, or the like. A plurality of heating rollers 118 may be arrayed in the direction indicated by the arrow C.

The backup roller 120 does not need to be heated, and may comprise a cooling roller with a cooling fluid being circulated therein, if necessary.

The cushion layer 27 is heated by the heating roller 118 to a temperature in a predetermined temperature range up to, i.e., equal to or below, the glass transition temperature (Tg). The glass transition temperature of the cushion layer 27 is obtained by detecting a tan δ value (loss coefficient) according to a viscoelastic measuring process and determining a temperature which maximizes the tan δ value.

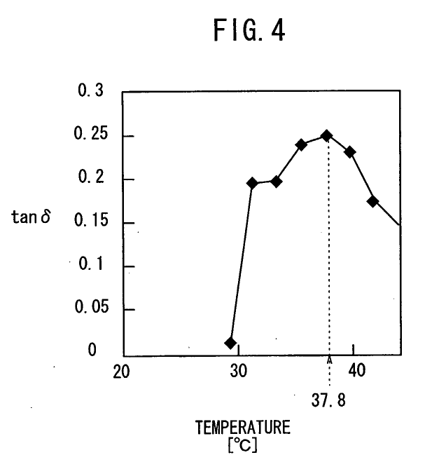

The relationship of temperatures and tan δ values of a laminated film was detected using a viscoelasticity measuring device manufactured by K.K. Toyo Baldwin, and data shown in FIG. 4 were obtained. According to the data shown in FIG. 4, the glass transition temperature of the cushion layer 27 was 37.8° C.

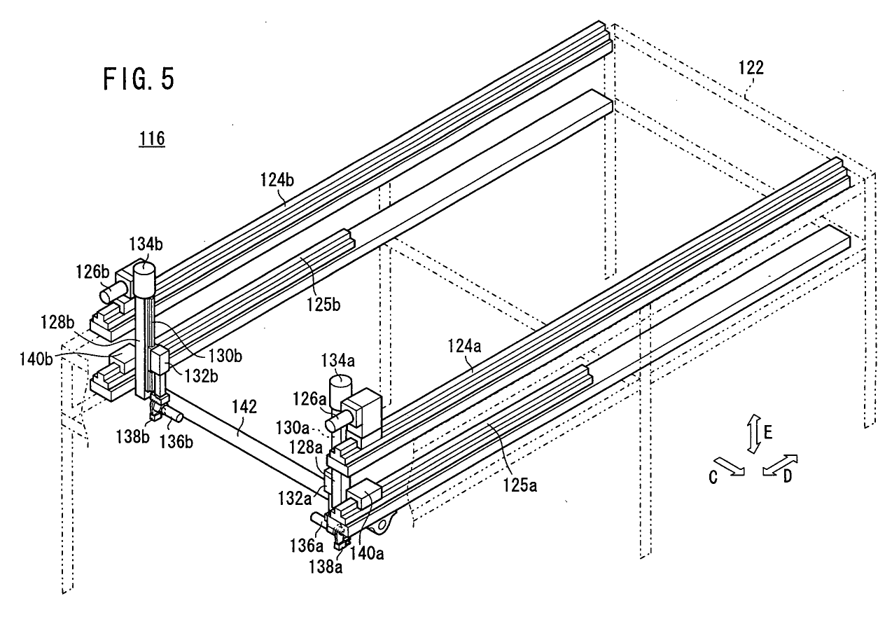

As shown in FIG. 5, the peeling mechanism 116 has a frame 122 supporting thereon a pair of upper guide rails 124a, 124b extending in the direction indicated by the arrow D which is perpendicular to the direction indicated by the arrow C along which the joined substrate 24a is fed. The frame 122 also supports a pair of lower guide rails 125a, 125b disposed below the upper guide rails 124a, 124b and also extending in the direction indicated by the arrow D. The lower guide rails 125a, 125b are shorter than the upper guide rails 124a, 124b. Self-propelled movable units 128a, 128b are movably supported respectively on the upper guide rails 124a, 124b. The self-propelled movable units 128a, 128b are actuatable by respective motors 126a, 126b for back-and-forth movement in the direction indicated by the arrow D along the guide rails 124a, 124b.

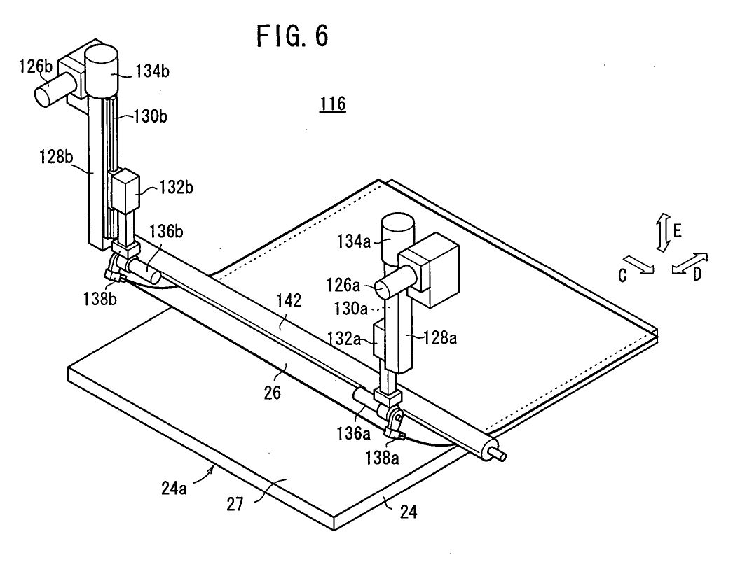

As shown in FIGS. 5 and 6, the self-propelled movable units 128a, 128b extend vertically in the direction indicated by the arrow E and have respective vertical guide rails 130a, 130b on their side surfaces which confront each other. Vertically movable bases 132a, 132b are movably supported on the guide rails 130a, 130b, respectively, and are actuatable by respective motors 134a, 134b for vertical movement in the direction indicated by the arrow E along the guide rails 130a, 130b.

Horizontally oriented rotary actuators 136a, 136b are mounted respectively on the vertically movable bases 132a, 132b. The rotary actuators 136a, 136b have respective horizontal rotatable shafts (not shown) to which respective chucks 138a, 138b are fixed. The chucks 138a, 138b are angularly movable by the rotary actuators 136a, 136b, and are positionally adjustable to a position in which the chucks 138a, 138b can grip opposite side edges of the base film 26 which project outwardly from the opposite ends of the glass substrate 24 of the joined substrate 24a in the direction in which it is fed, at a position where the base film 26 is to be peeled off from the joined substrate 24a.

As shown in FIG. 5, slide bases 140a, 140b are slidably supported on the respective lower guide rails 125a, 125b. A follower roller 142 has its opposite ends vertically movably supported on the slide bases 140a, 140b. The slide bases 140a, 140b are movable back and forth in unison with the movable units 128a, 128b between predetermined positions that are spaced in the direction indicated by the arrow D.

As shown in FIG. 1, a plurality of suction pads 144 for attracting and holding the glass substrate 24 of a joined substrate 24a are disposed beneath the peeling mechanism 116. The peeling mechanism 116 is spaced from the heating mechanism 112 by a distance which is long enough to allow a joined substrate 24a to be cooled between the heating mechanism 112 and the peeling mechanism 116.

The installation space of the manufacturing apparatus 20 is divided into a first clean room 152a and a second clean room 152b by a partition wall 150. The first clean room 152a houses therein the web reel-out mechanism 32, the peeling mechanism 34, and the masking tape applying mechanism 38. The second clean room 152b houses therein the detecting mechanism 44 and the other components following the detecting mechanism 44. The first clean room 152a and the second clean room 152b are connected to each other by a pass-through region 154.

Operation of the manufacturing apparatus 20 for carrying out a manufacturing method according to the present invention will be described below.

Initially for positioning the leading end of the photosensitive web 22 in place, the photosensitive web 22 is unreeled from the photosensitive web roll 22a accommodated in the web reel-out mechanism 32. The photosensitive web 22 is delivered through the peeling mechanism 34, the masking tape applying mechanism 38, and the joining mechanism 42 to the film feed rollers 100, which grip the leading end of the photosensitive web 22.

When a masking tape 36 is detected by the photosensitive sensor 82, the film feed rollers 100 are rotated based on a detected signal from the photosensitive sensor 82. The photosensitive web 22 is now fed a predetermined distance to the joining position by the film feed rollers 100, positioning the masking tape 36 at the joining position. Alternatively, a masking tape 36 may be detected downstream of the joining position, and the photosensitive web 22 may be stopped at a predetermined position.

The contact prevention roller 96 is lowered to prevent the photosensitive web 22 from contacting the rubber roller 90a. A glass substrate 24 is waiting immediately prior to the joining position. The photosensitive web 22 is now in an initial state of the manufacturing apparatus 20.

Operation of the functional components of the manufacturing apparatus 20 in a lamination mode will be described below.

As shown in FIG. 1, the photosensitive web 22 is unreeled from the web reel-out mechanism 32 and continuously fed to the peeling mechanism 34. In the peeling mechanism 34, the base film 26 of the photosensitive web 22 is attracted to the suction drum 46, and the protective film 30 is continuously peeled off from the photosensitive web 22. The protective film 30 is peeled off at a sharp peel-off angle by the peeling roller 46a and wound by the protective film takeup unit 50.

After the protective film 30 has been peeled off from the base film 26 by the peeling mechanism 34, the photosensitive web 22 is adjusted in tension by the tension control mechanism 52, and then fed to the masking tape applying mechanism 38.

In the masking tape applying mechanism 38, after the attracting member 60 has attracted the masking tape 36, the attracting member 60 and applying back base 62 hold the photosensitive web 22 while moving in synchronism with the photosensitive web 22, and apply the masking tape 36 to the photosensitive resin layer 29 (see FIG. 3).

The photosensitive web 22 with the masking tape 36 applied to a prescribed area of the photosensitive resin layer 29 is then fed to the detecting mechanism 44. In the detecting mechanism 44, as shown in FIG. 1, the photosensitive sensor 82 detects a boundary edge of the masking tape 36. Based on the detected positional information of the masking tape 36, the film feed rollers 100 are rotated to feed the photosensitive web 22 a predetermined distance to the joining mechanism 42. At this time, the contact prevention roller 96 is waiting above the photosensitive web 22 and the rubber roller 90b is disposed below the photosensitive web 22.

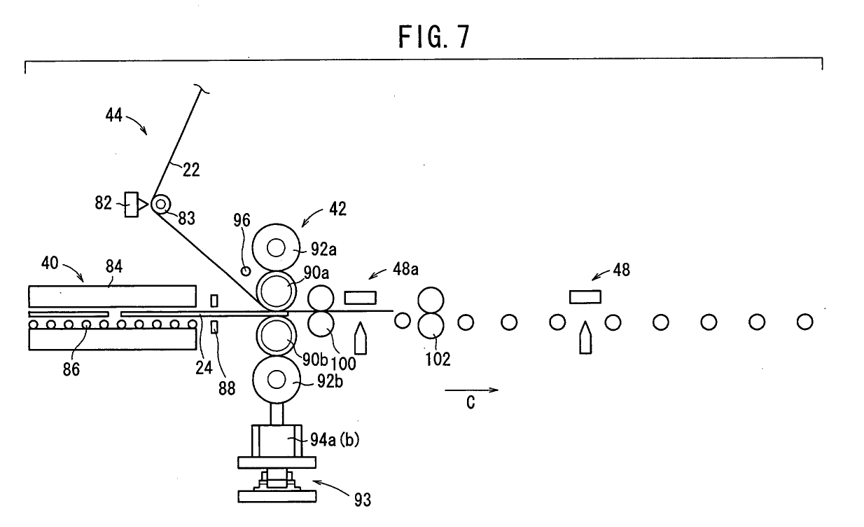

As shown in FIG. 7, the first glass substrate 24 which is preheated is fed to the joining position by the substrate feed mechanism 40. The glass substrate 24 is tentatively positioned between the rubber rollers 90a, 90b in alignment with the area of the photosensitive web 22 where a making tape 36 is applied to the photosensitive resin layer 29.

The glass substrate 24 is sandwiched under a predetermined pressing pressure between the rubber rollers 90a, 90b by the roller clamp unit 93. The rubber roller 90a is rotated to transfer, i.e., laminate, the photosensitive resin layer 29, which is melted with heat, to the glass substrate 24.

The photosensitive resin layer 29 is laminated onto the glass substrate 24 under such conditions that the photosensitive resin layer 29 is fed at a speed in the range from 1.0 m/min. to 10 m/min., the rubber rollers 90a, 90b have a temperature ranging from 110° C. to 140° C., and a hardness in the range from 40 to 90, and apply a pressure (linear pressure) ranging from 50 N/cm to 400 N/cm.

When the leading end of the glass substrate 24 reaches a position near the film feed rollers 100, the film feed rollers 100 are moved away from the glass substrate 24. When the leading end of the photosensitive web 22 which projects forwardly of the glass substrate 24 in the direction indicated by the arrow C reaches a predetermined position with respect to the web leading end cutting mechanism 48a, the web leading end cutting mechanism 48a is actuated to cut off the leading end of the photosensitive web 22. After having cut off the leading end of the photosensitive web 22, the web leading end cutting mechanism 48a returns to its standby position, and will not be used while the manufacturing apparatus 20 is in normal operation.

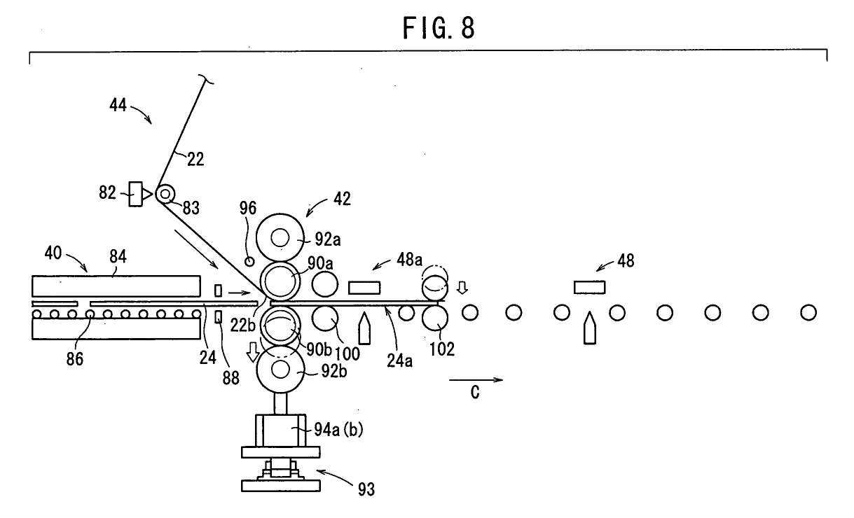

As shown in FIG. 8, when the photosensitive web 22 has been laminated onto the glass substrate 24 up to its trailing end by the rubber rollers 90a, 90b, the rotation of the rubber roller 90a is stopped, and a joined substrate 24a, which refers to the glass substrate 24 with the laminated photosensitive web 22, is clamped by the substrate feed rollers 102.

The rubber roller 90b is retracted away from the rubber roller 90a, unclamping the joined substrate 24a. The substrate feed rollers 102 then start rotating to feed the joined substrate 24a a predetermined distance in the direction indicated by the arrow C. The position 22b of the photosensitive web 22 which is to be brought between two adjacent glass substrates 24 is now displaced to a position beneath the rubber roller 90a.

A next glass substrate 24 is fed toward the joining position by the substrate feed mechanism 40. When the leading end of the next glass substrate 24 is positioned between the rubber rollers 90a, 90b, the rubber roller 90b is lifted, clamping the next glass substrate 24 and the photosensitive web 22 between the rubber rollers 90a, 90b. At the same time, the substrate feed rollers 102 clamp the joined substrate 24a. The rubber rollers 90a, 90b and the substrate feed rollers 102 are rotated to start laminating the photosensitive web 22 onto the glass substrate 24 and feed the joined substrate 24a in the direction indicated by the arrow C.

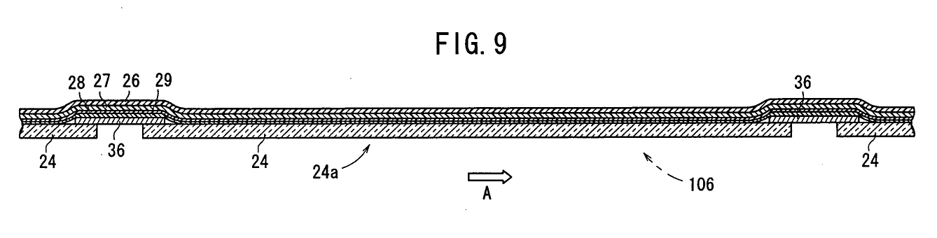

At this time, as shown in FIG. 9, the joined substrate 24a has opposite ends covered with respective masking tapes 36. Therefore, when the photosensitive resin layer 29 is transferred to the glass substrate 24, the photosensitive resin layer 29 is transferred to form something like a picture frame.

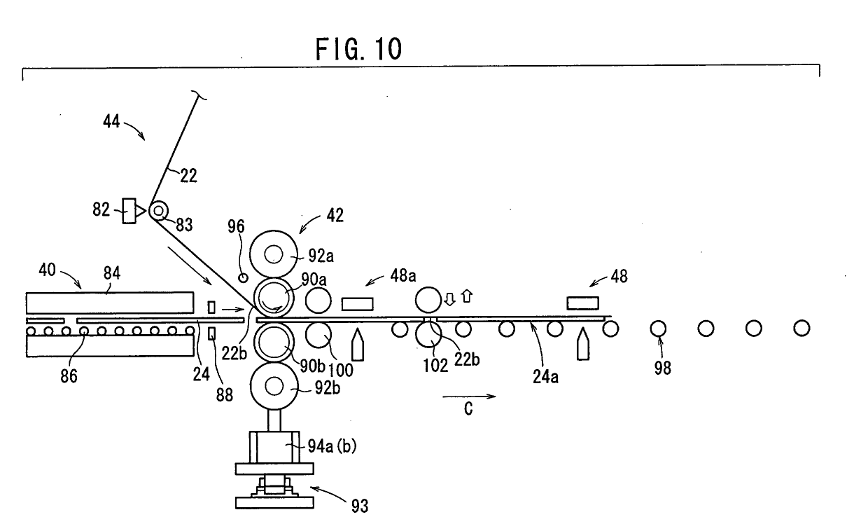

As shown in FIG. 10, when the trailing end of the first joined substrate 24a reaches the substrate feed rollers 102, the upper one of the substrate feed rollers 102 is lifted to unclamp the first joined substrate 24a, and the lower one of the substrate feed rollers 102 and the other rollers of the feed path 98 are continuously rotated to feed the joined substrate 24a. When the trailing end of the next, i.e., second, joined substrate 24a reaches a position near the rubber rollers 90a, 90b, the rubber rollers 90a, 90b and the substrate feed rollers 102 stop rotating.

The upper one of the substrate feed rollers 102 is lowered to clamp the second joined substrate 24a, and the rubber roller 90b is lowered to unclamp the second joined substrate 24a. Then, the substrate feed rollers 102 are rotated to grip and feed the second joined substrate 24a. The position 22b of the photosensitive web 22 which is to be brought between two adjacent glass substrates 24 is now displaced to the position beneath the rubber roller 90a, and the photosensitive web 22 is repeatedly laminated onto third and subsequent glass substrates 24.

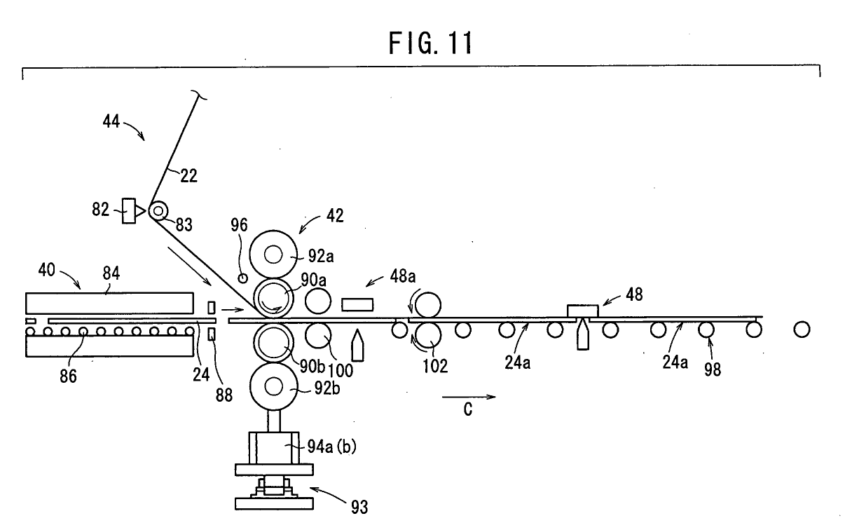

As shown in FIG. 11, when the position between two adjacent joined substrates 24a reaches a position corresponding to the inter-substrate web cutting mechanism 48, the inter-substrate web cutting mechanism 48 severs the photosensitive web 22 between the joined substrates 24a, i.e., intermediate through the masking tape 36, while moving in the direction indicated by the arrow C at the same speed as the joined substrates 24a. Thereafter, the inter-substrate web cutting mechanism 48 returns to a standby position, and the joined substrate 24a is fed in the direction indicated by the arrow C.

When the inter-substrate web cutting mechanism 48 and the web leading end cutting mechanism 48a cut off the photosensitive web 22, they move in synchronism with the photosensitive web 22 in the direction indicated by the arrow C. However, the inter-substrate web cutting mechanism 48 and the web leading end cutting mechanism 48a may move only transversely across the photosensitive web 22 to cut off the photosensitive web 22. The photosensitive web 22 may be cut off by a Thompson blade while it is held at rest, or may be cut off by a rotary blade while it is in motion.

Each joined substrate 24a that has been separated by the inter-substrate web cutting mechanism 48 is fed to the cooling mechanism 110 as shown in FIG. 1. After the joined substrate 24a is forcibly cooled to a room temperature of about 20° C. by cold air in the cooling mechanism 110, the joined substrate 24a is fed to the heating mechanism 112. In the heating mechanism 112, the joined substrate 24a is gripped by the heating roller 118 and the backup roller 120, and the heat of the heating roller 118 is directly transferred to the base film 26 of the joined substrate 24a.

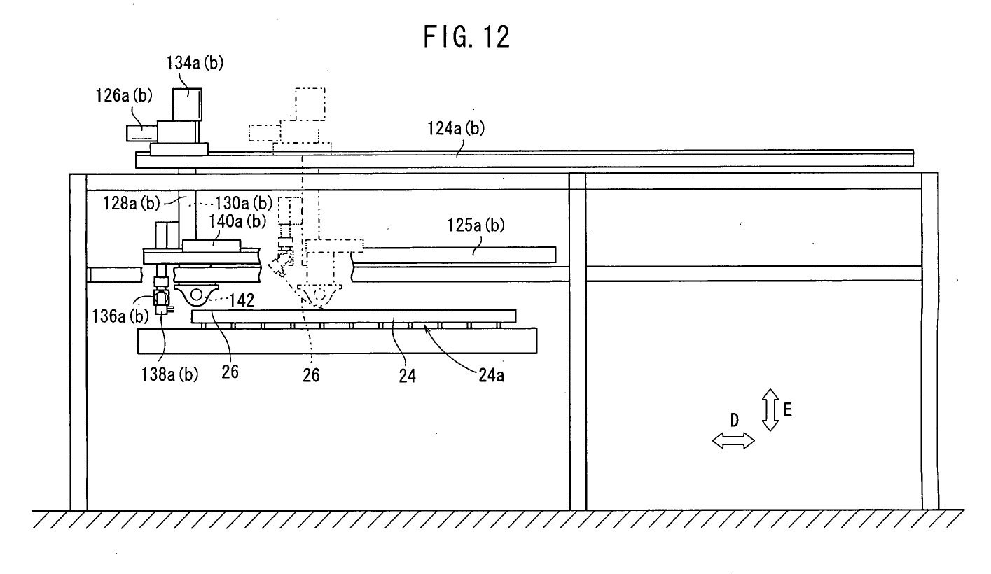

The cushion layer 27 is heated to a certain temperature through the base film 26, after which the joined substrate 24a is delivered to the peeling mechanism 116. In the peeling mechanism 116, the glass substrate 24 of the joined substrate 24a is attracted and held by the suction pads 144, and the chucks 138a, 138b are positioned near one side of the base film 26 in the direction indicated by the arrow D (see FIG. 12), the base film 26 having opposite ends projecting inwardly from the opposite ends of the glass substrate 24 in the direction in which it is fed.

The movable units 128a, 128b are moved toward the joined substrate 24a by the respective motors 126a, 126b, and the chucks 138a, 138b are opened and closed to grip the opposite ends of the base film 26 in the direction in which it is fed. The chucks 138a, 138b are turned by the rotary actuators 136a, 136b, and the vertically movable bases 132a, 132b and the movable units 128a, 128b are actuated in predetermined directions.

As shown in FIGS. 6 and 12, the chucks 138a, 138b are displaced along a predetermined peeling path, causing the base film 26 gripped by the chucks 138a, 138b to be separated from the cushion layer 27 and peeled off from the joined substrate 24a. At this time, the follower roller 142 moves in unison with the movable units 128a, 128b to a predetermined position in the direction indicated by the arrow D, allowing the base film 26 to be peeled smoothly well from the joined substrate 24a. When the base film 26 is peeled off from the joined substrate 24a, a photosensitive laminated body 114 is produced.

According to the first embodiment, the cushion layer 27 of the joined substrate 24a that has been forcibly cooled by the cooling mechanism 110 is heated to a temperature close to the glass transition temperature thereof by the heat applied from the heating mechanism 112 through the base film 26. Thereafter, the base film 26 is peeled off from the cushion layer 27 by the peeling mechanism 116.

Specifically, in the joining mechanism 42, the photosensitive web 22 is thermally compressed against the glass substrate 24 while being kept under predetermined tension, and hence tends to cause residual stresses to be developed in the cushion layer 27. Residual stresses also tend to be developed in the cushion layer 27 because the joined substrate 24a is forcibly cooled by the cooling mechanism 110. Thus, when the base film 26 is peeled off from the joined substrate 24a, the cushion layer 27 is liable to crack or be damaged due to the residual stresses developed therein. As a result, the cushion layer 27 suffers defects such as surface irregularities and has its quality lowered.

According to the first embodiment, before the base film 26 is peeled off, the cushion layer 27 is heated to a temperature close to the glass transition temperature thereof through the base film 26 to reduce the residual stresses developed in the cushion layer 27.

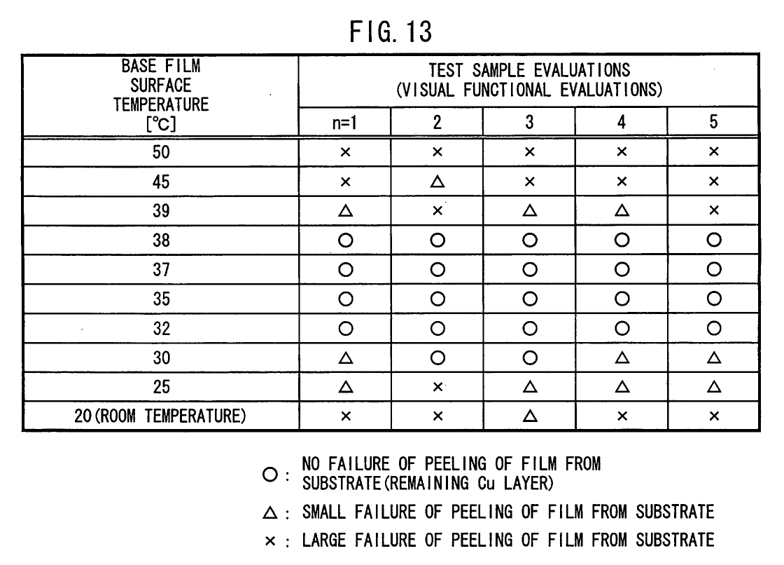

An experiment was conducted to detect peeling failures when the base film 26 was peeled off at various different surface temperatures of the base film 26. The results of the experiment are shown in FIG. 13. The experimental results shown in FIG. 13 indicate that the base film 26 can be peeled off well and a high-quality photosensitive laminated body 114 can be produced if the surface temperature of the base film 26 is set to a value within a temperature range from 32° C. to 38° C. which is generally below the glass transition temperature (37.8° C.) of the cushion layer 27.

The heating mechanism 112 heats the joined substrate 24a from the side of the base film 26 with the heating roller 118. Therefore, the peel-off interface between the cushion layer 27 and the base film 26 that is to be peeled off therefrom is heated to a desired temperature more quickly and accurately than if the peel-off interface is heated from the side of the glass substrate 24. The base film 26 can thus be peeled off from the cushion layer 27 accurately along the peel-off interface between the cushion layer 27 and the base film 26.

The peeling mechanism 116 is spaced a predetermined distance from the heating mechanism 112. The joined substrate 24a which has been heated to reduce residual stresses developed in the cushion layer 27 is cooled while it is being fed from the heating mechanism 112 to the peeling mechanism 116.

The follower roller 142 of the peeling mechanism 116 may be heated by a heating mechanism, not shown, and held in contact with the base film 26 to peel off the base film 26 from the cushion layer 27 while the base film 26 is being heated by the heating mechanism. The follower roller 142 may have hot air ejecting holes (not shown) as such a heating mechanism, and the base film 26 may be peeled off from the cushion layer 27 while the base film 26 on the joined substrate 24a is being heated by hot air ejected from the hot air ejecting holes of the follower roller 142 that is held out of contact with the base film 26. The peeling mechanism 116 may have a plurality of such follower rollers 142.

According to the first embodiment, the peeling mechanism 116 is arranged to peel off the base film 26 progressively in the direction indicated by the arrow D which extends across the direction, indicated by the arrow C, in which the joined substrate 24a is fed. However, the peeling mechanism 116 may be arranged to peel off the base film 26 progressively in the direction indicated by the arrow C which extends parallel to the direction in which the joined substrate 24a is fed.

A preheating mechanism (not shown) may be provided upstream of the heating mechanism 112 for assisting in heating the joined substrate 24a. The preheating mechanism may comprise an infrared power heater such as a coil heater, a carbon heater, a halogen heater, or the like, or an IR heater such as a ceramic heater, or any of various contact heating rollers.

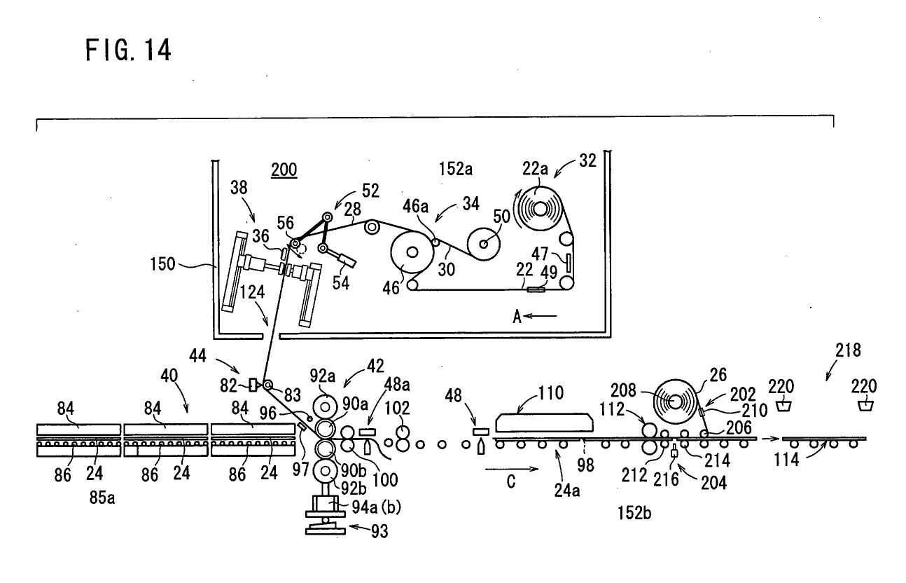

FIG. 14 schematically shows in side elevation a manufacturing apparatus 200 according to a second embodiment of the present invention. Those parts of the manufacturing apparatus 200 according to the second embodiment which are identical to those of the manufacturing apparatus 20 according to the first embodiment are denoted by identical reference characters, and will not be described in detail below.

The manufacturing apparatus 200 includes the inter-substrate web cutting mechanism 48 which is usually not used except for cutting off the photosensitive web 22 in case of trouble and separating the photosensitive web 22 to discharge defective sections. The manufacturing apparatus 200 has a peeling mechanism 202 which is disposed downstream of the cooling mechanism 110 and the heating mechanism 112. The peeling mechanism 202 serves to continuously peel off, together with masking tapes 36, an elongate base film 26 joined to glass substrates 24 that are spaced at given intervals. The peeling mechanism 202 has a prepeeler 204, a peeling roller 206 having a relatively small diameter, a takeup shaft 208, and an automatic joining unit 210. The peeling roller 206 has a suction cup (not shown) for attracting the base film 26 only at the time the peeling roller 206 starts to peel off the base film 26 that is to be wound around the takeup shaft 208.

The prepeeler 204 has a pair of nip roller assemblies 212, 214 and a peeling bar 216. The nip roller assemblies 212, 214 are movable toward and away from each other in the direction in which glass substrates 24 are fed. The nip roller assemblies 212, 214 grip glass substrates 24 therebetween. The peeling bar 216 is vertically movable between adjacent glass substrates 24.

The peeling mechanism 202 is followed downstream by a measuring unit 218 for measuring the area of a photosensitive resin layer 29 that is actually applied to a glass substrate 24. The measuring unit 218 has a plurality of spaced cameras 220 each comprising a CCD or the like. Specifically, the measuring unit 218 has four cameras 220, for example, for capturing the images of four corners of a glass substrate 24 to which a photosensitive resin layer 29 is joined and for image processing.

The measuring unit 218 may comprise color sensors or laser sensors for detecting end faces of a glass substrate 24 or may comprise a combination of LED sensors, photodiode sensors, or line sensors for detecting end faces of a glass substrate 24. At least two of these sensors should desirably be employed to capture the image of each of the end faces for detecting the linearity of each of the end faces.

Surface inspection units (not shown) may be employed to detect surface defects of photosensitive laminated bodies, such as surface irregularities caused by the photosensitive web 22 itself, laminated film density irregularities caused by the manufacturing facility, wrinkles, striped patterns, dust particles, and other foreign matter. When such a surface defect is detected, the manufacturing apparatus 200 issues an alarm, ejects defective products, and manages subsequent processes based on the detected surface defect.

According to the second embodiment, the joined substrate 24a to which the photosensitive web 22 is laminated by the joining mechanism 42 is delivered to the prepeeler 204 which pre-peels off the base film 26. Thereafter, the joined substrate 24a is sent to the peeling mechanism 202. In the peeling mechanism 202, the takeup shaft 208 is rotated to continuously wind the base film 26 and the masking tape 36 from the joined substrate 24a. After the photosensitive web 22 is cut off in case of trouble and separated to discharge defective sections, the leading end of the base film 26 on a joined substrate 24a to which the photosensitive web 22 starts being laminated and the trailing end of the base film 26 wound on the takeup shaft 208 are automatically joined to each other by the automatic joining unit 210.

The photosensitive laminated body 114 from which the base film 26 and the masking tape 36 are peeled off is placed in an inspecting station combined with the measuring unit 218. In the inspecting station, the photosensitive laminated body 114 is fixed in place, and the four cameras 220 capture the images of the glass substrate 24 and the photosensitive resin layer 29. The captured images are processed to determine applied positions.

In the inspecting station, the photosensitive laminated body 114 may be fed along without being stopped, and transverse ends of the photosensitive laminated body 114 may be detected by cameras or image scanning, and longitudinal ends thereof may be detected by timing sensors or the like. Then, the photosensitive laminated body 114 may be measured based on the detected data produced by the cameras or image scanning and the sensors.

According to the second embodiment, after the photosensitive web 22 has been laminated onto glass substrates 24, the photosensitive web 22 between two adjacent joined substrates 24a is not cut off. Rather, the base film 26 and the masking tape 36 can continuously be peeled off from the joined substrate 24a and wound around the takeup shaft 208 which is in rotation. The base film 26 and the masking tape 36 that have been peeled off can easily be processed. The base film 26 and the masking tape 36 can be processed more easily if they are made of the same material.

The masking tapes 36 are made economical if they are made of a water-soluble material, e.g., paper (clean paper). The adhesive layers of the making tapes 36 may be made of a water-soluble or heat-peelable adhesive.

According to the second embodiment, the photosensitive laminated body 114 can be manufactured automatically and efficiently.

In the first and second embodiments, the peeling mechanism 116 and the peeling mechanism 202 may be combined with a dedusting air applying mechanism, not shown. Although the heating mechanism 112 is employed for heating the base film 26 of the joined substrate 24a in direct contact therewith in the first and second embodiments, it may be replaced with any of various contactless heating mechanisms.

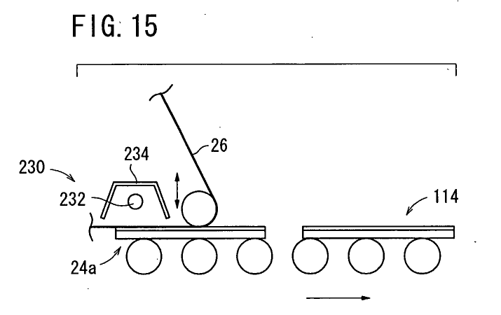

FIG. 15 schematically shows in side elevation a heating mechanism 230 of a manufacturing apparatus according to a third embodiment of the present invention.

As shown in FIG. 15, the heating mechanism 230 has a heater 232 for heating the joined substrate 24a from the side of the base film 26 out of contact therewith. The heater 232 is covered with a cover 234. The heater 232 may comprise an infrared bar header, a halogen heater, a carbon heater, a ceramics type heater, or a coil heater. Alternatively, the heater 232 may comprise a plate heater or a ceramics heater having an angularly displaceable or swinging mechanism, or a plurality of light lamps for emitting light which does not contain light components in a wavelength range to which the photosensitive web 22 is sensitive.

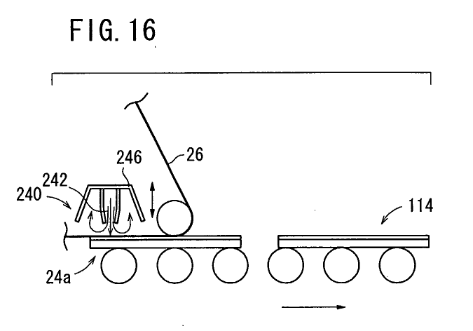

FIG. 16 schematically shows in side elevation a heating mechanism 240 of a manufacturing apparatus according to a fourth embodiment of the present invention.

As shown in FIG. 16, the heating mechanism 240 has a hot air ejecting nozzle 242 for heating the joined substrate 24a from the side of the base film 26 out of contact therewith. The nozzle 242 is covered with a cover 246. A suction structure (not shown) is provided between the cover 246 and the nozzle 242 for preventing hot air ejected from the nozzle 242 from spreading out.

According to the first through fourth embodiments, as shown in FIG. 2, the photosensitive web 22 including the base film 26, the cushion layer 27, the intermediate layer 28, and the photosensitive resin layer 29 is employed as the laminated body but the present invention is not limited to such structure. Alternatively, for example, the laminated body may comprise a laminated assembly of a support layer (the base film 26) and at least one resin layer (the cushion layer 27 or the photosensitive resin layer 29) which have different coefficients of thermal expansion. Similar advantageous effects can be obtained.

The peel-off interface is not limited to being present between the base film 26 and the cushion layer 27, but may be present between the cushion layer 27 and the intermediate layer 28 or between the intermediate layer 28 and the photosensitive resin layer 29.

Although certain preferred embodiments of the present invention have been shown and described in detail, it should be understood that various changes and modifications may be made therein without departing from the scope of the appended claims.

1. A method of manufacturing a laminated substrate assembly by bonding a laminated body including a support layer and at least one resin layer laminated thereon, to a substrates such that said resin layer faces said substrate, and thereafter, peeling off said support layer from said resin layer to produce a laminated substrate assembly, said method comprising the steps of:
cooling a joined substrate, which includes said resin layer and said substrate bonded thereto; and
heating said resin layer to a temperature in a predetermined temperature range up to a glass transition temperature thereof.

2. A method according to claim 1, further comprising the step of:
peeling off said support layer from said resin layer while heating said resin layer.

3. A method according to claim 1, further comprising the steps of:
cooling said joined substrate which has been heated in said step of heating said resin layer; and
thereafter, peeling off said support layer from said resin layer.

4. A method according to claim 1, wherein said resin layer is heated from the side of said support layer.

5. A method according to claim 1, further comprising the steps of:
bonding said laminated body, which is elongate, integrally to a plurality of said substrates; and
thereafter, peeling off said support layer continuously from each of said substrates to produce said laminated substrate assembly.

6. A method according to claim 1, further comprising the steps of:
bonding said laminated body, which is elongate, integrally to a plurality of said substrates;
cutting off said laminated body between said substrates; and
thereafter, peeling off said support layer from each of said substrates to produce said laminated substrate assembly.

7. A method according to claim 1, wherein said laminated body comprises an elongate photosensitive web in the form of a laminated assembly of said support layer, a thermoplastic resin layer disposed as said resin layer on said support layer, and a photosensitive resin layer disposed on said thermoplastic resin layer and bonded to said substrate, and said support layer is peeled off from said thermoplastic resin layer or said photosensitive resin layer.

8. A method according to claim 1, wherein said predetermined temperature range comprises a range from 32° C. to 38° C.

9. An apparatus for manufacturing a laminated substrate assembly by bonding a laminated body including a support layer and at least one resin layer laminated thereon, to a substrate such that said resin layer faces said substrate, and thereafter, peeling off said support layer from said resin layer to produce a laminated substrate assembly, said apparatus comprising:
a cooling mechanism for cooling a joined substrate, which includes said resin layer and said substrates bonded thereto; and
a heating mechanism for heating said resin layer to a temperature in a predetermined temperature range up to a glass transition temperature thereof.

10. An apparatus according to claim 9, further comprising a peeling mechanism with a heating mechanism, for peeling off said support layer from said resin layer while heating said resin layer with said heating mechanism.

11. An apparatus according to claim 9, wherein said heating mechanism is disposed on the side of said support layer for heating said resin layer from the side of said support layer.

12. An apparatus according to claim 9, wherein said laminated body, which is elongate, is bonded integrally to a plurality of said substrates, said apparatus further comprising:
a peeling mechanism for peeling off said support layer continuously from each of said substrates to produce said laminated substrate assembly after said laminated body has been bonded to said substrates.

13. An apparatus according to claim 9, wherein said laminated body, which is elongate, is bonded integrally to a plurality of said substrates, and said laminated body is cut off between said substrates, said apparatus further comprising:
a peeling mechanism for peeling off said support layer from each of said substrates to produce said laminated substrate assembly after said laminated body has been bonded to said substrates and said laminated body has been cut off between said substrates.

14. An apparatus according to claim 9, wherein said laminated body comprises an elongate photosensitive web in the form of a laminated assembly of said support layer, a thermoplastic resin layer disposed as said resin layer on said support layer, and a photosensitive resin layer disposed on said thermoplastic resin layer and bonded to said substrate, and said support layer is peeled off from said thermoplastic resin layer or said photosensitive resin layer.

15. An apparatus according to claim 9, wherein said predetermined temperature range comprises a range from 32° C. to 38° C.
